(19) United States
(12) Patent Application Publication
(10) Pub. No.: US 2026/0004983 A1
(43) Pub. Date: Jan. 1, 2026

(54) SENSING CONTROL DEVICE WITH LOAD BALANCING FUNCTION

(71) Applicant: Xiamen PVTECH Co., Ltd., Xiamen (CN)

(72) Inventors: CHENGQUAN XU, Xiamen (CN); ZHIRONG LIN, Xiamen (CN); LIANGLIANG CAO, Xiamen (CN); FUXING LU, Xiamen (CN)

(73) Assignee: Xiamen PVTECH Co., Ltd., Xiamen (CN)

(21) Appl. No.: 19/250,009

(22) Filed: Jun. 25, 2025

(30) Foreign Application Priority Data
Jun. 27, 2024 (CN) 202410850966.8

(51) Int. Cl. H01H 47/00; G01R 31/327

(52) U.S. Cl. CPC H01H 47/002; G01R 31/3278

(57) ABSTRACT

A sensing control device includes an input terminal, an output terminal, a plurality of switches, a processing module and a sensing module. The input terminal is connected to a power source. The output terminal is connected to a controlled device. The switches are connected to the input terminal and the output terminal. The processing module is connected to the switches. The sensing module is connected to the processing module. The processing module executes an aging estimation process to estimate the aging value of each of the switches upon receiving a sensing signal from the sensing module. The processing module selects one of the switches based on the aging values of the switches, and turns on the selected switch to activate the controlled device.

### BACKGROUND OF THE INVENTION

### 1. Field of the Invention

The present invention relates to a sensing control device, in particular to a sensing control device with a load balancing function.

### 2. Description of the Prior Art

A currently available AC sensing controller turns on a relay to activate a controlled device when it detects a moving object and generates a sensing signal. However, a currently available relay typically has a rated switching life of only around 100,000 times. As a result, when the AC sensing controllers are used in specific applications (such as garages), they are limited by the relay's rated switching life and may fail within a short period. Therefore, the currently available AC sensing controllers can no longer meet actual requirements.

### SUMMARY OF THE INVENTION

One embodiment of the present invention provides a sensing control device with a load balancing function, which includes an input terminal, an output terminal, a plurality of switches, a processing module and a sensing module. The input terminal is connected to a power source. The output terminal is connected to a controlled device. The switches are connected to the input terminal and the output terminal. The processing module is connected to the switches. The sensing module is connected to the processing module. The processing module executes an aging estimation process to estimate the aging value of each of the switches upon receiving a sensing signal from the sensing module. The processing module selects one of the switches based on the aging values of the switches, and turns on the selected switch to activate the controlled device.

In one embodiment, the aging value of the selected switch is lowest among the switches.

In one embodiment, the processing module multiplies the accumulated operating duration of each of the switches by an operating duration coefficient to obtain a first value, multiplies the switching number of the switch by a switching number coefficient to obtain a second value, multiplies the average operating current of the switch by an overcurrent coefficient to obtain a third value, and calculates the sum of the first value, the second value, and the third value to serve as the aging value of the switch.

In one embodiment, the operating duration coefficient is the reciprocal of a normal operating duration of the switch. The switching number coefficient is the reciprocal of the rated switching life of the switch. The overcurrent coefficient is the reciprocal of the rated switching life of the switch under the overcurrent condition.

In one embodiment, the sensing control device further includes a current detection module. The switches are connected to the output terminal via the current detection module, and the current detection module is connected to the processing module

In one embodiment, the processing module turns off the selected switch when the current detected by the current detection module is lower than a preset current value after the selected switch is turned on, and re-executes the aging estimation process.

In one embodiment, the sensing module is a microwave sensor, an infrared sensor, or other similar components.

In one embodiment, the processing module is a microcontroller, a central-processing unit, an application-specific integrated circuit, a field-programmable gate array, or other similar components.

In one embodiment, the switches are relays.

In one embodiment, the power source is a utility power.

The sensing control device with the load balancing function in accordance with the embodiments of the present invention may have the following advantages:
(1) In one embodiment of the present invention, the sensing control device includes an input terminal, an output terminal, a plurality of switches, a processing module and a sensing module. The input terminal is connected to a power source. The output terminal is connected to a controlled device. The switches are connected to the input terminal and the output terminal. The processing module is connected to the switches. The sensing module is connected to the processing module. The processing module executes an aging estimation process to estimate the aging value of each of the switches upon receiving a sensing signal from the sensing module. The processing module selects one of the switches based on the aging values of the switches, and turns on the selected switch to activate the controlled device. The selected switch is the one with the lowest aging value among the switches. Therefore, the sensing control device features a unique load balancing function by executing the aging estimation process to select the switch with the lowest aging value for activation, thereby significantly enhancing the service life of the sensing control device to meet the requirements of different applications.
(2) In one embodiment of the present invention, the processing module of the sensing control device can first multiply the accumulated operating duration of the switch by an operating duration coefficient to obtain a first value, then multiply the switching number by a switching number coefficient to obtain a second value, and finally multiply the average operating current by an overcurrent coefficient to obtain a third value. The processing module then adds the first, second, and third values to obtain the aging value of the switch. The operating duration coefficient is the reciprocal of the normal operating duration of the switch, the switching number coefficient is the reciprocal of the rated switching life of the switch, and the overcurrent coefficient is the reciprocal of the rated switching life of the switch under the overcurrent condition. This estimation mechanism enables a more accurate reflection of the aging status of each switch, thereby allowing the processing module to perform the aging estimation process with great precision. Accordingly, the sensing control device can meet actual requirements.
(3) In one embodiment of the present invention, the sensing control device further includes a current detection module. The switches are connected to the output terminal via the current detection module, and the current detection module is connected to the processing module. When the selected switch is turned on, and the current detected by the current detection module is lower than a preset current value, the processing module turns off the selected switch and re-executes the aging estimation process. Through this mechanism, in the event of the selected switch failure, the processing module can promptly re-execute the aging estimation process to select another switch with a lower aging value. This fault detection mechanism ensures the proper operation of the sensing control device, thereby further enhancing the service life thereof.
(4) In one embodiment of the present invention, the sensing module of the sensing control device may be a microwave sensor or an infrared sensor to provide different sensing functions. Accordingly, the sensing control device can be applied in various intelligent systems, such as intelligent garage systems, intelligent home systems, etc. As such, the sensing control device can be more comprehensive in application and align with future development trends.
(5) In one embodiment of the present invention, the sensing control device features a simple design and can achieve the desired effects without significantly increasing cost. Therefore, the sensing control device offers high practicality and meets market demands.

Further scope of applicability of the present application will become more apparent from the detailed description given hereinafter. However, it should be understood that the detailed description and specific examples, while indicating exemplary embodiments of the present invention, are given by way of illustration only, since various changes and modifications within the spirit and scope of the present invention will become apparent to those skilled in the art from this detailed description.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a block diagram of a circuit structure of a sensing control device with a load balancing function in accordance with a first embodiment of the present invention.

FIG. 2 is a schematic view of an operating state of the sensing control device with the load balancing function in operation in accordance with a first embodiment of the present invention.

FIG. 3 is a block diagram of a circuit structure of a sensing control device with a load balancing function in accordance with a second embodiment of the present invention.

FIG. 4 is a first schematic view of an operating state of the sensing control device with the load balancing function in operation in accordance with the second embodiment of the present invention.

FIG. 5 is a second schematic view of the operating state of the sensing control device with the load balancing function in operation in accordance with the second embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

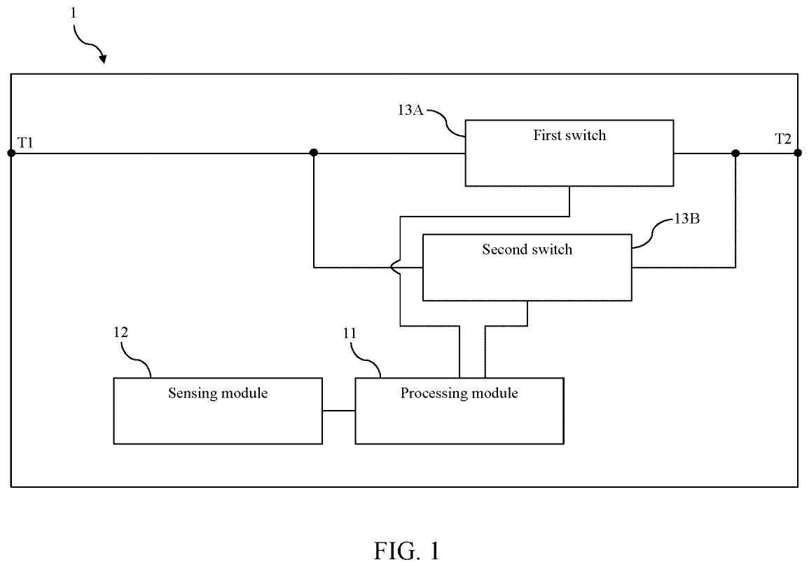

Please refer to FIG. 1, which is a block diagram of a circuit structure of a sensing control device with a load balancing function in accordance with a first embodiment of the present invention. As shown in FIG. 1, the sensing control device 1 includes an input terminal T1, an output terminal T2, a plurality of switches, a processing module 11, and a sensing module 12.

The input terminal T1 is connected to a power source (not shown in the drawings). In this embodiment, the sensing control device 1 is an AC sensing control device, and the power source is a utility power. In another embodiment, the power source may be a battery or other similar component.

The output terminal T2 is connected to a controlled device (not shown in the drawings). In one embodiment, the controlled device is a lighting device, such as an LED lamp, light bulb, or other similar component. In another embodiment, the controlled device may be a fan, air conditioner, or other similar component.

The switches are connected between the input terminal T1 and the output terminal T2. The input terminal T1 is connected to the output terminal T2 via the switches. In this embodiment, the switches include a first switch 13A and a second switch 13B. In another embodiment, the switches may include three or more switches. The number of switches may vary depending on actual requirements. In this embodiment, the switches are relays. In another embodiment, the switches may be semiconductor switches or other similar components.

The processing module 11 is connected to the switches. In this embodiment, the processing module 11 is a microcontroller unit (MCU). In another embodiment, the processing module 11 may be a central-processing unit (CPU), an application-specific integrated circuit (ASIC), a field-programmable gate array (FPGA), or other similar component.

The sensing module 12 is connected to the processing module 11. In this embodiment, the sensing module 12 is a microwave sensor. In another embodiment, the sensing module 12 may be an infrared sensor (e.g., PIR sensor) or other similar component.

It should be noted that the present embodiment is provided for illustrative purposes only and should not be construed as limiting the scope of the invention. Equivalent modifications or variations based on this embodiment shall still fall within the scope of the present invention.

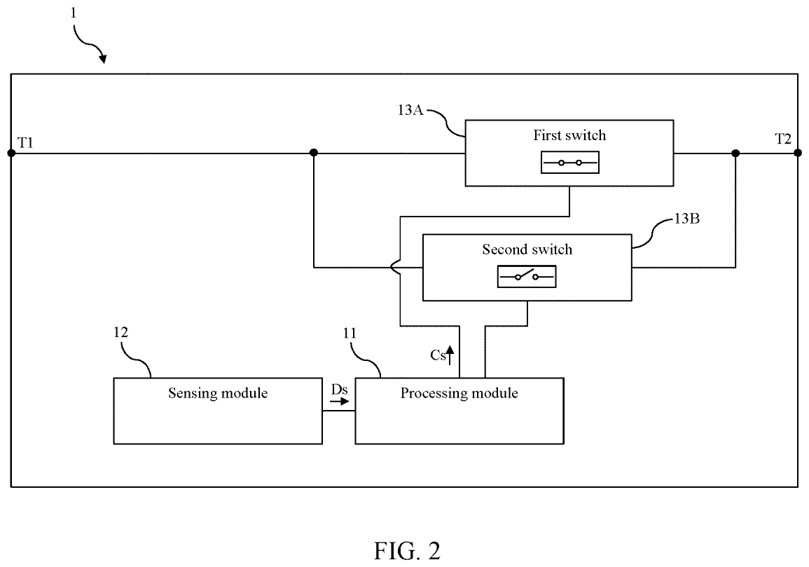

Please refer to FIG. 2, which is a schematic view of an operating state of the sensing control device with the load balancing function in operation in accordance with a first embodiment of the present invention. As shown in FIG. 2, after detecting a moving object, the sensing module 12 generates a sensing signal Ds. Upon receiving the sensing signal Ds from the sensing module 12, the processing module 11 executes an aging estimation process based on the sensing signal Ds to estimate the aging value of each of the switches (the first switch 13A and the second switch 13B). For example, the processing module 11 multiplies the accumulated operating duration of the first switch 13A by an operating duration coefficient to obtain a first value, then multiplies the switching number of the first switch 13A by a switching number coefficient to obtain a second value, and further multiplies the average operating current of the first switch 13A by an overcurrent coefficient to obtain a third value. The processing module 11 then calculates the sum of the first, second, and third values to obtain the aging value of the first switch 13A, as shown in Equation (1) given below:

$$U = a \times T + b \times N + c \times I \qquad ( 1 )$$

In Equation (1), U stands for the aging value of the first switch 13A; a stands for the operating duration coefficient of the first switch 13A; T stands for the accumulated operating duration of the first switch 13A; b stands for the switching number coefficient of the first switch 13A; N stands for the switching number of the first switch; c stands for the overcurrent coefficient of the first switch 13A; I stands for the average operating current of the first switch 13A. The operating duration coefficient a is the reciprocal of the normal operating duration of the first switch 13A. The switching number coefficient b is the reciprocal of the rated switching life of the first switch 13A (the rated switching life refers to the maximum number of switching operations at which the first switch 13A is expected to fail). The overcurrent coefficient c is the reciprocal of the rated switching life of the first switch 13A under the overcurrent condition. The processing module 11 calculates the aging value of the second switch 13B in the same manner.

The processing module 11 then selects one of the first switch 13A and the second switch 13B based on the aging values of the first switch 13A and the second switch 13B, and turns on the selected switch to activate the controlled device. The selected switch has the lowest aging value among the switches. In this embodiment, the aging value of the first switch 13A is lower than that of the second switch 13B. Therefore, the processing module 11 selects the first switch 13A and sends a control signal Cs to turn it on, thereby activating the controlled device. Each time the sensing module 12 generates a sensing signal Ds, the processing module 11 executes the aging estimation process based on the sensing signal Ds to select the switch with the lowest aging value. If the aging value of the first switch 13A is higher than that of the second switch 13B, the processing module 11 will select the second switch 13B and send a control signal Cs to turn it on to activate the controlled device.

This estimation mechanism takes into account the accumulated operating duration, switching number, and overcurrent conditions. Therefore, the aging value obtained through this mechanism can more objectively and accurately reflect the aging condition of each switch, allowing the processing module 11 to perform the aging estimation process with high precision.

From the above, in this embodiment, the sensing control device 1 features a special load balancing function. It can execute the aging estimation process to select the switch with the lowest aging value and turn it on to activate the controlled device. As a result, the switches can achieve a load-balanced state, significantly enhancing the service life of the sensing control device 1 and meeting the requirements of various applications.

Furthermore, in this embodiment, the processing module 11 multiplies the accumulated operating duration of each switch by the operating duration coefficient to obtain a first value, multiplies the switching number by the switching number coefficient to obtain a second value, and multiplies the average operating current by the overcurrent coefficient to obtain a third value. The processing module then calculates the sum of the first, second, and third values to obtain the aging value of each switch. The operating duration coefficient is the reciprocal of the normal operating duration of the switch. The switching number coefficient is the reciprocal of the rated switching life of the switch. The overcurrent coefficient is the reciprocal of the rated switching life of the switch under the overcurrent condition. The aging value obtained through this estimation mechanism can more accurately reflect the aging condition of each switch, thereby allowing the processing module 11 to precisely execute the aging estimation process. As a result, the sensing control device 1 can meet actual requirements.

In addition, the sensing control device 1 may further include a current detection module. The switches are connected to the output terminal T2 through the current detection module, and the current detection module is connected to the processing module 11. When the selected switch is turned on and the current detected by the current detection module is lower than a preset current value, the processing module 11 turns off the selected switch and re-executes the aging estimation process. Through this mechanism, if the selected switch fails, the processing module 11 can quickly re-execute the aging estimation process to select another switch with a lower aging value. This specialized fault detection mechanism ensures the proper operation of the sensing control device 1 and further enhances its service life.

The embodiment just exemplifies the present invention and is not intended to limit the scope of the present invention; any equivalent modification and variation according to the spirit of the present invention is to be also included within the scope of the following claims and their equivalents.

It is worthy to point out that when currently available AC sensing controllers are used in specific applications (such as garages), they are limited by the relay's rated switching life and may fail within a short period. Therefore, the currently available AC sensing controllers can no longer meet actual requirements. By contrast, according to one embodiment of the present invention, the sensing control device includes an input terminal, an output terminal, a plurality of switches, a processing module and a sensing module. The input terminal is connected to a power source. The output terminal is connected to a controlled device. The switches are connected to the input terminal and the output terminal. The processing module is connected to the switches. The sensing module is connected to the processing module. The processing module executes an aging estimation process to estimate the aging value of each of the switches upon receiving a sensing signal from the sensing module. The processing module selects one of the switches based on the aging values of the switches, and turns on the selected switch to activate the controlled device. The selected switch is the one with the lowest aging value among the switches. Therefore, the sensing control device features a unique load balancing function by executing the aging estimation process to select the switch with the lowest aging value for activation, thereby significantly enhancing the service life of the sensing control device to meet the requirements of different applications.

Also, according to one embodiment of the present invention, the processing module of the sensing control device can first multiply the accumulated operating duration of the switch by an operating duration coefficient to obtain a first value, then multiply the switching number by a switching number coefficient to obtain a second value, and finally multiply the average operating current by an overcurrent coefficient to obtain a third value. The processing module then adds the first, second, and third values to obtain the aging value of the switch. The operating duration coefficient is the reciprocal of the normal operating duration of the switch, the switching number coefficient is the reciprocal of the rated switching life of the switch, and the overcurrent coefficient is the reciprocal of the rated switching life of the switch under the overcurrent condition. This estimation mechanism enables a more accurate reflection of the aging status of each switch, thereby allowing the processing module to perform the aging estimation process with great precision. Accordingly, the sensing control device can meet actual requirements.

Further, according to one embodiment of the present invention, the sensing control device further includes a current detection module. The switches are connected to the output terminal via the current detection module, and the current detection module is connected to the processing module. When the selected switch is turned on, and the current detected by the current detection module is lower than a preset current value, the processing module turns off the selected switch and re-executes the aging estimation process. Through this mechanism, in the event of the selected switch failure, the processing module can promptly re-execute the aging estimation process to select another switch with a lower aging value. This fault detection mechanism ensures the proper operation of the sensing control device, thereby further enhancing the service life thereof.

Moreover, according to one embodiment of the present invention, the sensing module of the sensing control device may be a microwave sensor or an infrared sensor to provide different sensing functions. Accordingly, the sensing control device can be applied in various intelligent systems, such as intelligent garage systems, intelligent home systems, etc. As such, the sensing control device can be more comprehensive in application and align with future development trends.

Furthermore, according to one embodiment of the present invention, the sensing control device features a simple design and can achieve the desired effects without significantly increasing cost. Therefore, the sensing control device offers high practicality and meets market demands. As set forth above, the sensing control device in accordance with the embodiments of the present invention can definitely achieve great technical effects.

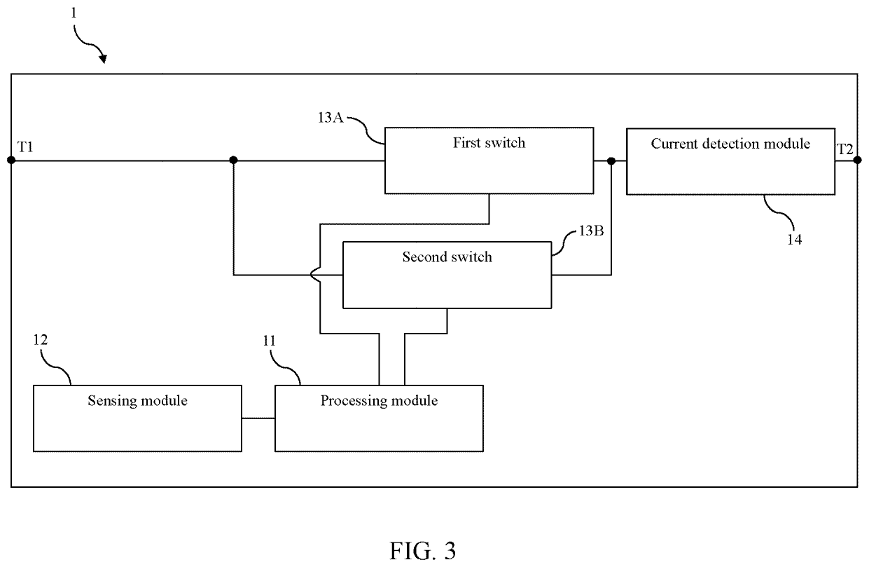

Please refer to FIG. 3, which is a block diagram of a circuit structure of a sensing control device with a load balancing function in accordance with a second embodiment of the present invention. As shown in FIG. 3, the sensing control device 1 includes an input terminal T1, an output terminal T2, a plurality of switches, a processing module 11, and a sensing module 12. The input terminal T1 is connected to a power source (not shown in the drawings). The output terminal T2 is connected to a controlled device (not shown in the drawings). The switches are connected between the input terminal T1 and the output terminal T2. The processing module 11 is connected to the switches. The sensing module 12 is connected to the processing module 11.

The above components are similar to those of the previous embodiment, so will not be described therein again. The difference between this embodiment and the previous embodiment is that the sensing control device 1, in this embodiment, further includes a current detection module 14. The switches are connected to the output terminal T2 through the current detection module 14, and the current detection module 14 is connected to the processing module 11. In this embodiment, the current detection module 14 may be a current detector. In another embodiment, the current detection module 14 may be a circuit with current detection capability.

The embodiment just exemplifies the present invention and is not intended to limit the scope of the present invention; any equivalent modification and variation according to the spirit of the present invention is to be also included within the scope of the following claims and their equivalents.

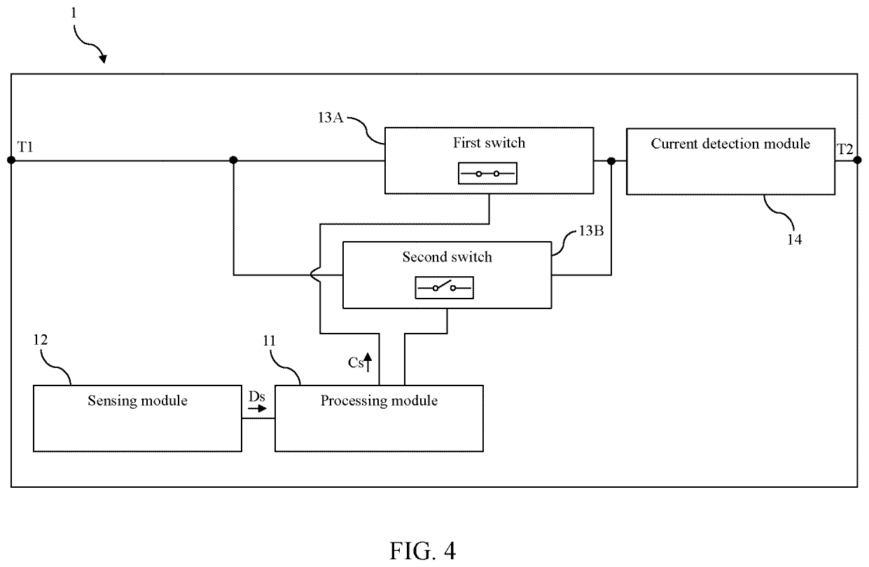

Please refer to FIG. 4, which is a first schematic view of an operating state of the sensing control device with the load balancing function in operation in accordance with the second embodiment of the present invention. As shown in FIG. 4, the sensing module 12 generates a sensing signal Ds after detecting a moving object. Upon generation of the sensing signal Ds by the sensing module 12, the processing module 11 executes an aging estimation process based on the sensing signal Ds to estimate the aging values of the switches (the first switch 13A and second switch 13B).

The processing module 11 then selects one of the switches based on the aging values of the first switch 13A and the second switch 13B, and turns on the selected switch to activate the controlled device. The selected switch is the one with the lowest aging value among the switches. In this embodiment, the aging value of the first switch 13A is lower than that of the second switch 13B. Therefore, the processing module 11 selects the first switch 13A and sends a control signal Cs to turn on the first switch 13A, thereby activating the controlled device. Each time the sensing module 12 generates a sensing signal Ds, the processing module 11 executes the aging estimation process based on the sensing signal Ds to select the switch with the lowest aging value.

As previously stated, the sensing control device 1 of this embodiment also has a specific load balancing function. It executes the aging estimation process to select the switch with the lowest aging value and turns on that switch to activate the controlled device. In this way, the switches can achieve a load-balanced state, significantly extending the service life of the sensing control device 1 to meet the requirements of different applications.

Similarly, the processing module 11 multiplies the accumulated operating duration of each switch by the operating duration coefficient to obtain a first value, multiplies the switching number by the switching number coefficient to obtain a second value, and then multiplies the average operating current by the overcurrent coefficient to obtain a third value. The processing module then calculates the sum of the first, second, and third values to obtain the aging value of the switch. The operating duration coefficient is the reciprocal of the normal operating duration of the switch, the switching number coefficient is the reciprocal of the rated switching life, and the overcurrent coefficient is the reciprocal of the rated switching life under overcurrent conditions. The aging value obtained through this estimation mechanism can more accurately reflect the aging status of each switch, allowing the processing module 11 to execute the aging estimation process with high precision. Therefore, the sensing control device 1 can meet actual requirements.

The embodiment just exemplifies the present invention and is not intended to limit the scope of the present invention; any equivalent modification and variation according to the spirit of the present invention is to be also included within the scope of the following claims and their equivalents.

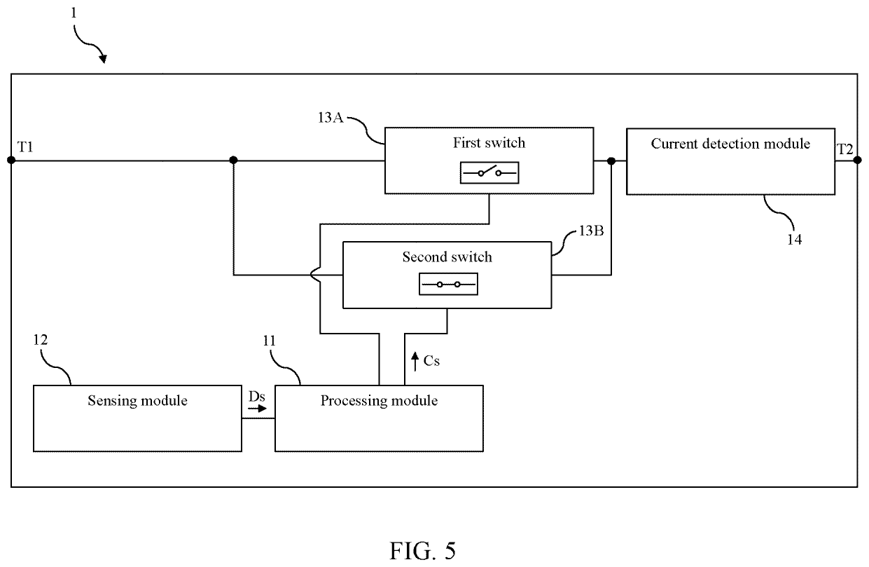

Please refer to FIG. 5, which is a second schematic view of the operating state of the sensing control device with the load balancing function in operation in accordance with the second embodiment of the present invention. As shown in FIG. 5, after the processing module 11 turns on the first switch 13A, the current detection module 14 detects the output current. If the current detected by the current detection module 14 is lower than a preset current value, the processing module 11 determines that the first switch 13A may be faulty, cuts off the first switch 13A, and re-executes the aging estimation process to select another switch. In this embodiment, the processing module 11 determines the first switch 13A as faulty and sends a control signal Cs to turn on the second switch 13B. The above fault determination condition may be adjusted according to actual requirements.

In addition, the sensing control device 1 may also include a current detection module. The switches are connected to the output terminal T2 through the current detection module, and the current detection module is connected to the processing module 11. When the selected switch is turned on and the current detected by the current detection module is lower than a preset current value, the processing module 11 cuts off the selected switch and re-executes the aging estimation process. Through this mechanism, if the selected switch fails, the processing module 11 can quickly re-execute the aging estimation process to select another switch with a lower aging value. This special fault detection mechanism ensures that the sensing control device 1 can operate normally, further enhancing its service life.

As described above, the sensing control device 1 of this embodiment also includes a current detection module 14. The switches are connected to the output terminal T2 through the current detection module 14, and the current detection module 14 is connected to the processing module 11. When the selected switch is turned on and the current detected by the current detection module 14 is lower than a preset current value, the processing module 11 cuts off the selected switch and re-executes the aging estimation process. Through this mechanism, if the selected switch fails, the processing module 11 can quickly re-execute the aging estimation process to select another switch with a lower aging value. This special fault detection mechanism ensures that the sensing control device 1 can operate normally, further enhancing its service life.

Furthermore, in this embodiment, the sensing module 12 of the sensing control device 1 may be a microwave sensor or an infrared sensor, providing different sensing functions. As such, the sensing control device 1 can be applied to various intelligent systems, such as intelligent garage systems, intelligent home systems, and so on. Therefore, the sensing control device 1 has broader application potential and better aligns with future development trends.

The embodiment just exemplifies the present invention and is not intended to limit the scope of the present invention; any equivalent modification and variation according to the spirit of the present invention is to be also included within the scope of the following claims and their equivalents.

To sum up, according to one embodiment of the present invention, the sensing control device includes an input terminal, an output terminal, a plurality of switches, a processing module and a sensing module. The input terminal is connected to a power source. The output terminal is connected to a controlled device. The switches are connected to the input terminal and the output terminal. The processing module is connected to the switches. The sensing module is connected to the processing module. The processing module executes an aging estimation process to estimate the aging value of each of the switches upon receiving a sensing signal from the sensing module. The processing module selects one of the switches based on the aging values of the switches, and turns on the selected switch to activate the controlled device. The selected switch is the one with the lowest aging value among the switches. Therefore, the sensing control device features a unique load balancing function by executing the aging estimation process to select the switch with the lowest aging value for activation, thereby significantly enhancing the service life of the sensing control device to meet the requirements of different applications.

Also, according to one embodiment of the present invention, the processing module of the sensing control device can first multiply the accumulated operating duration of the switch by an operating duration coefficient to obtain a first value, then multiply the switching number by a switching number coefficient to obtain a second value, and finally multiply the average operating current by an overcurrent coefficient to obtain a third value. The processing module then adds the first, second, and third values to obtain the aging value of the switch. The operating duration coefficient is the reciprocal of the normal operating duration of the switch, the switching number coefficient is the reciprocal of the rated switching life of the switch, and the overcurrent coefficient is the reciprocal of the rated switching life of the switch under the overcurrent condition. This estimation mechanism enables a more accurate reflection of the aging status of each switch, thereby allowing the processing module to perform the aging estimation process with great precision. Accordingly, the sensing control device can meet actual requirements.

Further, according to one embodiment of the present invention, the sensing control device further includes a current detection module. The switches are connected to the output terminal via the current detection module, and the current detection module is connected to the processing module. When the selected switch is turned on, and the current detected by the current detection module is lower than a preset current value, the processing module turns off the selected switch and re-executes the aging estimation process. Through this mechanism, in the event of the selected switch failure, the processing module can promptly re-execute the aging estimation process to select another switch with a lower aging value. This fault detection mechanism ensures the proper operation of the sensing control device, thereby further enhancing the service life thereof.

Moreover, according to one embodiment of the present invention, the sensing module of the sensing control device may be a microwave sensor or an infrared sensor to provide different sensing functions. Accordingly, the sensing control device can be applied in various intelligent systems, such as intelligent garage systems, intelligent home systems, etc. As such, the sensing control device can be more comprehensive in application and align with future development trends.

Furthermore, according to one embodiment of the present invention, the sensing control device features a simple design and can achieve the desired effects without significantly increasing cost. Therefore, the sensing control device offers high practicality and meets market demands.

It will be apparent to those skilled in the art that various modifications and variations can be made to the disclosed embodiments. It is intended that the specification and examples be considered as exemplary only, with a true scope of the present invention being indicated by the following claims and their equivalents.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A sensing control device with a load balancing function, comprising:
an input terminal connected to a power source;
an output terminal connected to a controlled device;
a plurality of switches connected to the input terminal and the output terminal;
a processing module connected to the switches; and
a sensing module connected to the processing module;
wherein the processing module is configured to execute an aging estimation process to estimate an aging value of each of the switches upon receiving a sensing signal from the sensing module, and select one of the switches based on the aging values of the switches, and turn on a selected switch to activate the controlled device.

2. The sensing control device with the load balancing function as claimed in claim 1, wherein the aging value of the selected switch is lowest among the switches.

3. The sensing control device with the load balancing function as claimed in claim 1, wherein the processing module is configured to multiply an accumulated operating duration of each of the switches by an operating duration coefficient to obtain a first value, multiply a switching number of the switch by a switching number coefficient to obtain a second value, multiply an average operating current of the switch by an overcurrent coefficient to obtain a third value, and calculate a sum of the first value, the second value, and the third value to serve as the aging value of the switch.

4. The sensing control device with the load balancing function as claimed in claim 3, wherein the operating duration coefficient is a reciprocal of a normal operating duration of the switch, the switching number coefficient is a reciprocal of a rated switching life of the switch, and the overcurrent coefficient is a reciprocal of a rated switching life of the switch under an overcurrent condition.

5. The sensing control device with the load balancing function as claimed in claim 1, further comprising a current detection module, wherein the switches are connected to the output terminal via the current detection module, and the current detection module is connected to the processing module.

6. The sensing control device with the load balancing function as claimed in claim 5, wherein the processing module is configured to turn off the selected switch when a current detected by the current detection module is lower than a preset current value after the selected switch is turned on, and re-execute the aging estimation process.

7. The sensing control device with the load balancing function as claimed in claim 1, wherein the sensing module is a microwave sensor or an infrared sensor.

8. The sensing control device with the load balancing function as claimed in claim 1, wherein the processing module is a microcontroller, a central-processing unit, an application-specific integrated circuit, or a field-programmable gate array.

9. The sensing control device with the load balancing function as claimed in claim 1, wherein the switches are relays.

10. The sensing control device with the load balancing function as claimed in claim 1, wherein the power source is a utility power.
